(19) United States
(12) Patent Application Publication
(10) Pub. No.: US 2012/0319880 A1
(43) Pub. Date: Dec. 20, 2012

(54) SUCCESSIVE APPROXIMATION AD CONVERTER AND MOBILE WIRELESS DEVICE

(75) Inventors: Akinori MATSUMOTO, Osaka (JP); Shiro SAKIYAMA, Kyoto (JP); Yusuke TOKUNAGA, Kyoto (JP); Ichiro KUWABARA, Ehime (JP)

(73) Assignee: Panasonie Corporation, Osaka (JP)

(21) Appl. No.: 13/597,936

(22) Filed: Aug. 29, 2012

Related U.S. Application Data
(63) Continuation of application No. PCT/JP2010/005606, filed on Sep. 14, 2010.

(30) Foreign Application Priority Data
Mar. 9, 2010 (JP) 2010-051483

(51) Int. Cl. H03M 1/12

(52) U.S. Cl. 341/122

(57) ABSTRACT

A controller controls first and second supply switches so that, during a sampling period, a ground voltage is supplied to n first up-capacitors and n second up-capacitors while a power supply voltage is supplied to n first down-capacitors and n second down-capacitors. The controller also controls the first and second supply switches based on the result of comparison by a comparator during each of n bit determination periods so that a first analog voltage at a first sampling node and a second analog voltage at a second sampling node gradually approach each other.

### CROSS-REFERENCE TO RELATED APPLICATIONS

This is a continuation of PCT International Application PCT/JP2010/005606 filed on Sep. 14, 2010, which claims priority to Japanese Patent Application No. 2010-051483 filed on Mar. 9, 2010. The disclosures of these applications including the specifications, the drawings, and the claims are hereby incorporated by reference in their entirety.

### BACKGROUND

The technology disclosed herein relates to AD converters which convert an analog signal into a digital code, and more particularly, to successive approximation AD converters.

At present, a successive approximation AD converter is known as an AD converter which has a relatively simple circuit configuration, is highly compatible with the CMOS process, which can be performed at relatively low cost, and provides a medium conversion rate and accuracy, and therefore, is used in a variety of products (e.g., Japanese Patent Publication No. 2007-142863 (Patent Document 1), M. Van. Elzakker et al., “A 1.9 μW 4.40/Conversion-step 10b 1MS/s Charge-Redistribution ADC,” ISSCC Dig. Tech. Papers, pp. 244-245, February 2008 (Non-Patent Document 1), etc.).

FIG. 14 shows a configuration of a successive approximation AD converter described in Non-Patent Document 1. The successive approximation AD converter converts an analog signal Vin into a 6-bit digital code (six bit values D95-D90). The successive approximation AD converter includes six capacitors 95-90, a supply switch 901 including six inverters, a comparator 902, and a controller 903. One ends of the capacitors 95-90 are connected to a sampling node Ns9. If the capacitance value of the capacitor 90 is C₀, the capacitance values of the capacitors 91, 92, 93, 94, and 95 are 2C₀, 4C₀, 8C₀, 16C₀, and 32C₀, respectively. In response to a control of the controller 903, the supply switch 901 supplies one of a reference voltage Vref and a ground voltage Vss, as control voltages V95-V90, to the other ends of the capacitors 95-90. The comparator 902 compares an analog voltage V901 with a comparative voltage Vx. The controller 903 controls a sampling switch SW9 and the supply switch 901 and determines the bit values D95-D90 in synchronization with a sampling clock fs and an internal clock fck.

Next, operation of the conventional successive approximation AD converter will be described with reference to FIG. 15.

<<ST901>>

The controller 903 sets the control voltage V95 to the reference voltage Vref and the control voltages V94-V90 to the ground voltage Vss in synchronization with a rising edge of the sampling clock fs, and switches the sampling switch SW9 from the off state to the on state.

<<ST902>>

Next, the controller 903 switches the sampling switch SW9 from the on state to the off state in synchronization with a falling edge of the sampling clock fs.

<<ST903>>

Next, the controller 903 selects the bit value D95 (the most significant bit (MSB) value) of the bit values D95-D90, as a bit value to be processed (hereinafter referred to as a bit value Di, here, i=95-90).

<<ST904>>

Next, the controller 903 determines whether or not the analog voltage V901 is lower than the comparative voltage Vx, based on the result of comparison by the comparator 902. If the analog voltage V901 is lower than the comparative voltage Vx, control proceeds to step ST905, and otherwise, control proceeds to step ST906.

<<ST905>>

If the analog voltage V901 is lower than the comparative voltage Vx, the controller 903 determines that the bit value Di is “0” in synchronization with a rising edge of the internal clock fck. The controller 903 also switches a control voltage (hereinafter represented by a control voltage V(i−1)) corresponding to a bit value succeeding the bit value Di, of the control voltages V95-V90, from the ground voltage Vss to the reference voltage Vref in synchronization with a falling edge of the internal clock fck. For example, when the bit value Di is the bit value D95, the controller 903 switches the control voltage V94 corresponding to the bit value D94 from the ground voltage Vss to the reference voltage Vref Next, the controller 903 selects one succeeding the bit value Di of the bit values D95-D90, as a bit value to be processed. Next, control proceeds to step ST907.

<<ST906>>

On the other hand, if the analog voltage V901 is not lower than the comparative voltage Vx, the controller 903 determines that the bit value Di is “1” in synchronization with a rising edge of the internal clock fck. The controller 903 also switches a control voltage (hereinafter represented by a control voltage V1) corresponding to the bit value Di, of the control voltages V95-V90, from the reference voltage Vref to the ground voltage Vss, and the control voltage V(i−1) from the ground voltage Vss to the reference voltage Vref, in synchronization with a falling edge of the internal clock fck. Thereafter, the controller 903 selects one succeeding the bit value Di of the bit values D95-D90, as a bit value to be processed. Next, control proceeds to step ST907.

<<ST907>>

Next, the controller 903 determines whether or not the bit value Di is the bit value D90 (the least significant bit (LSB) value). If the bit value Di is not the bit value D90, control proceeds to step ST904, and if the bit value Di is the bit value D90, control proceeds to step ST908.

<<ST908>>

Next, the controller 903 determines whether or not the analog voltage V901 is lower than the comparative voltage Vx, based on the result of comparison by the comparator 902. If the analog voltage V901 is lower than the comparative voltage Vx, control proceeds to step ST909, and otherwise, control proceeds to step ST910.

<<ST909, ST910>>

If the analog voltage V901 is lower than the comparative voltage Vx, the controller 903 determines that the bit value D90 is “0” in synchronization with a rising edge of the internal clock fck (ST909). On the other hand, if the analog voltage V901 is not lower than the comparative voltage Vx, the controller 903 determines that the bit value D90 is “1” in synchronization with a rising edge of the internal clock fck (ST910).

### SUMMARY

Here, movement of charge in the successive approximation AD converter of FIG. 14 will be described with reference to FIGS. 16A and 16B. In FIGS. 16A and 16B, a capacitor 900 corresponds to a combination (combined capacitor) of the capacitors 93-90. If the capacitance value of the capacitor 95 is 2C, the capacitance value of the capacitor 94 is C, and the capacitance value of the capacitor 900 is approximated by C.

In step ST903, as shown in FIG. 16A, the reference voltage Vref is applied to the other end of the capacitor 95, and the ground voltage Vss is applied to the other ends of the capacitors 94 and 900. If the analog voltage V901 is not lower than the comparative voltage Vx, in step ST906 the control voltage V95 applied to the other end of the capacitor 95 is switched from the reference voltage Vref to the ground voltage Vss, and the control voltage V94 applied to the other end of the capacitor 94 is switched from the ground voltage Vss to the reference voltage Vref. In this case, as shown in FIG. 16B, charges Q1, Q2, and Q3 move in the capacitors 94, 900, and 95, i.e., charge is redistributed in the capacitors 94, 95, and 900. The charge Q1 which, after the control voltage is switched, moves in the capacitor 94 (i.e., the capacitor 94 connected to a supply source of the charge) to which the reference voltage Vref is applied, corresponds to charge which is consumed by the charge redistribution. Here, the charge Q1 is represented by:

$$\begin{matrix}Q 1 = C \{ Vref - V ( k + 1 ) \} - C \{ Vss - V ( k ) \} \\ = C \cdot Vref + C \{ V ( k ) - V ( k + 1 ) \}\end{matrix} \qquad ( 1 )$$

where V(k) is the analog voltage V901 before the switching of the control voltage, and V(k+1) is the analog voltage V901 after the switching of the control voltage.

The first term on the right side of the above expression means that, due to the switching of the control voltage, charge (C·Vref) has moved from the power supply to the ground. The second term on the right side of the expression means that charge corresponding to the change amount of the analog voltage V901 has moved. In other words, the charge (C·Vref) is consumed every time step ST906 is executed.

Thus, in the conventional successive approximation AD converter, charge moves from the power supply to the ground due to switching of the control voltage, and therefore, it is difficult to reduce the power consumption of the successive approximation AD converter.

The present disclosure describes implementations of a successive approximation AD converter whose power consumption can be reduced.

According to one aspect of the present disclosure, a successive approximation AD converter for converting first and second analog signals whose voltage values are complementary to each other into a digital code including (n+1) bit values, where n≧2, includes a first capacitor DA converter including n first up-capacitors and n first down-capacitors each having a binary-weighted capacitance value, one ends of the n first up-capacitors and the n first down-capacitors being connected to a first sampling node, and a first supply switch configured to supply one of a ground voltage and a power supply voltage to the other ends of the n first up-capacitors and the n first down-capacitors, a second capacitor DA converter including n second up-capacitors and n second down-capacitors each having a binary-weighted capacitance value, one ends of the n second up-capacitors and the n second down-capacitors being connected to a second sampling node, and a second supply switch configured to supply one of the ground voltage and the power supply voltage to the other ends of the n second up-capacitors and the n second down-capacitors, first and second sampling switches configured to sample the first and second analog signals for the first and second sampling nodes, respectively, during a sampling period, a comparator configured to compare a first analog voltage at the first sampling node with a second analog voltage at the second sampling node, and a controller configured to control the first and second supply switches so that, during the sampling period, the ground voltage is supplied to the other ends of the n first up-capacitors and the n second up-capacitors while the power supply voltage is supplied to the other ends of the n first down-capacitors and the n second down-capacitors, determine the (n+1) bit values sequentially from a most significant bit value by determining, during each of n bit determination periods corresponding to the n bit values excluding a least significant bit value of the (n+1) bit values and a least significant bit determination period corresponding to the least significant bit value, one corresponding to the bit determination period of the (n+1) bit values based on a result of comparison by the comparator, and control the first and second supply switches based on the result of comparison by the comparator during each of the n bit determination periods so that the first and second analog voltages gradually approach each other.

In the successive approximation AD converter, in each of the first and second capacitor DA converters, the capacitor array is divided into an up-capacitor array (the n up-capacitors) and a down-capacitor array (the n down-capacitors). By controlling the up-capacitor array and the down-capacitor array separately, the power consumption of the first and second capacitor DA converters can be reduced. As a result, the power consumption of the successive approximation AD converter can be reduced.

Note that, in the successive approximation AD converter, during each of the n bit determination periods, if the first analog voltage is lower than the second analog voltage, the controller may control the first and second supply switches so that the power supply voltage and the ground voltage are supplied to ones corresponding to the bit determination period of the n first up-capacitors and the n second down-capacitors, respectively, and if the first analog voltage is not lower than the second analog voltage, the controller may control the first and second supply switches so that the ground voltage and the power supply voltage are supplied to ones corresponding to the bit determination period of the n first up-capacitors and the n second down-capacitors, respectively.

The first capacitor DA converter may further include a first input capacitor connected between the first sampling node and a ground node to which the ground voltage is applied. The second capacitor DA converter may further include a second input capacitor connected between the second sampling node and the ground node. With this configuration, the input range of the successive approximation AD converter can be adjusted.

Note that the first and second capacitor DA converters may each further include first and second coupling capacitors. One end of the first coupling capacitor may be connected to one ends of p of the n first up-capacitors and p of the n first down-capacitors corresponding to most significant p bits of the digital code, and the first sampling node. The other end of the first coupling capacitor may be connected to one ends of q of the n first up-capacitors and q of the n first down-capacitors corresponding to least significant q bits excluding the least significant bit of the digital code, where p+q=n. The one ends of the q first up-capacitors and the q first down-capacitors may be connected via the first coupling capacitor to the first sampling node. One end of the second coupling capacitor may be connected to one ends of p of the n second up-capacitors and p of the n second down-capacitors corresponding to the most significant p bits of the digital code, and the second sampling node. The other end of the second coupling capacitor may be connected to the one ends of q of the n second up-capacitors and q of the n second down-capacitors corresponding to the least significant q bits excluding the least significant bit of the digital code. The one ends of the q second up-capacitors and the q second down-capacitors may be connected via the second coupling capacitor to the second sampling node. With this configuration, the area where the first and second capacitor DA converters are mounted can be reduced.

Note that the successive approximation AD converter may further includes a plurality of first correction capacitors, one ends of the plurality of first correction capacitors being connected to the other end of the first coupling capacitor, a first capacitor corrector configured to switch connection states between the other ends of the plurality of first correction capacitors and a ground node to which the ground voltage is applied, a plurality of second correction capacitors, one ends of the plurality of second correction capacitors being connected to the other end of the second coupling capacitor, and a second capacitor corrector configured to switch connection states between the other ends of the plurality of second correction capacitors and the ground node. With this configuration, the linearity of the first and second capacitor DA converters can be maintained, and therefore, the linearity of the successive approximation AD converter can be improved.

Alternatively, the successive approximation AD converter may further include a plurality of first offset adjustment capacitors, one ends of the plurality of first offset adjustment capacitors being connected to the other end of the first coupling capacitor, a first offset adjuster configured to supply one of the ground voltage and the power supply voltage to the other ends of the plurality of first offset adjustment capacitors, a plurality of second offset adjustment capacitors, one ends of the plurality of second offset adjustment capacitors being connected to the other end of the second coupling capacitor, and a second offset adjuster configured to supply one of the ground voltage and the power supply voltage to the other ends of the plurality of second offset adjustment capacitors. With this configuration, the offset of the comparator can be adjusted. As a result, the offset of the successive approximation AD converter can be adjusted.

According to another aspect of the present disclosure, a successive approximation AD converter for converting an analog signal into a digital code including (n+1) bit values, where n≧2, includes a capacitor DA converter including n up-capacitors and n down-capacitors each having a binary-weighted capacitance value, one ends of the n up-capacitors and the n down-capacitors being connected to a sampling node, and a supply switch configured to supply one of a ground voltage and a power supply voltage to the other ends of the n up-capacitors and the n down-capacitors, a sampling switch configured to sample the analog signal for the sampling node during a sampling period, a comparator configured to compare an analog voltage at the sampling node with a comparative voltage, and a controller configured to control the supply switch so that, during the sampling period, the ground voltage is supplied to the other ends of the n up-capacitors while the power supply voltage is supplied to the other ends of the n down-capacitors, determine the (n+1) bit values sequentially from a most significant bit value by determining, during each of n bit determination periods corresponding to the n bit values excluding a least significant bit value of the (n+1) bit values and a least significant bit determination period corresponding to the least significant bit value, one corresponding to the bit determination period of the (n+1) bit value based on a result of comparison by the comparator, and control the supply switch based on the result of comparison by the comparator during each of the n bit determination periods so that the analog voltage gradually approaches the comparative voltage.

In the successive approximation AD converter, in the capacitor DA converter, the capacitor array is divided into an up-capacitor array (the n up-capacitors) and a down-capacitor array (the n down-capacitors). By controlling the up-capacitor array and the down-capacitor array separately, the power consumption of the capacitor DA converter can be reduced. As a result, the power consumption of the successive approximation AD converter can be reduced.

### BRIEF DESCRIPTION OF THE DRAWINGS

FIG. 1 is a diagram showing an example configuration of a successive approximation AD converter according to a first embodiment.

FIG. 2 is a diagram for describing operation of the successive approximation AD converter of FIG. 1.

FIG. 3 is a diagram showing specific example operation of the successive approximation AD converter of FIG. 1.

FIGS. 4A and 4B are diagrams for describing movement of charge.

FIG. 5 is a diagram showing an example configuration of a first variation of the successive approximation AD converter of FIG. 1.

FIG. 6 is a diagram showing an example configuration of a second variation of the successive approximation AD converter of FIG. 1.

FIG. 7 is a diagram showing an example configuration of a third variation of the successive approximation AD converter of FIG. 1.

FIG. 8 is a diagram showing an example configuration of a fourth variation of the successive approximation AD converter of FIG. 1.

FIG. 9 is a diagram showing an example configuration of a successive approximation AD converter according to a second embodiment.

FIG. 10 is a diagram for describing operation of the successive approximation AD converter of FIG. 9.

FIG. 11 is a diagram showing an example configuration of a first variation of the successive approximation AD converter of FIG. 9.

FIG. 12 is a diagram showing an example configuration of a second variation of the successive approximation AD converter of FIG. 9.

FIG. 13 is a diagram showing an example configuration of a mobile wireless device.

FIG. 14 is a diagram showing an example configuration of a conventional successive approximation AD converter.

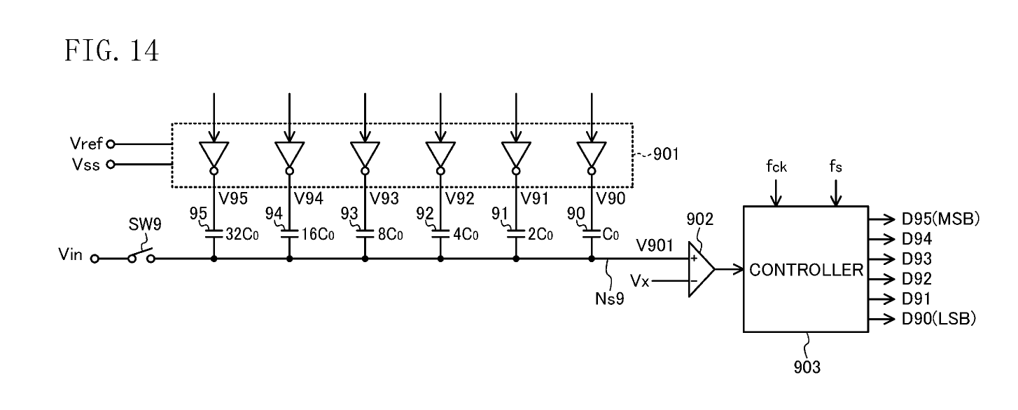

FIG. 15 is a diagram for describing operation of the conventional successive approximation AD converter.

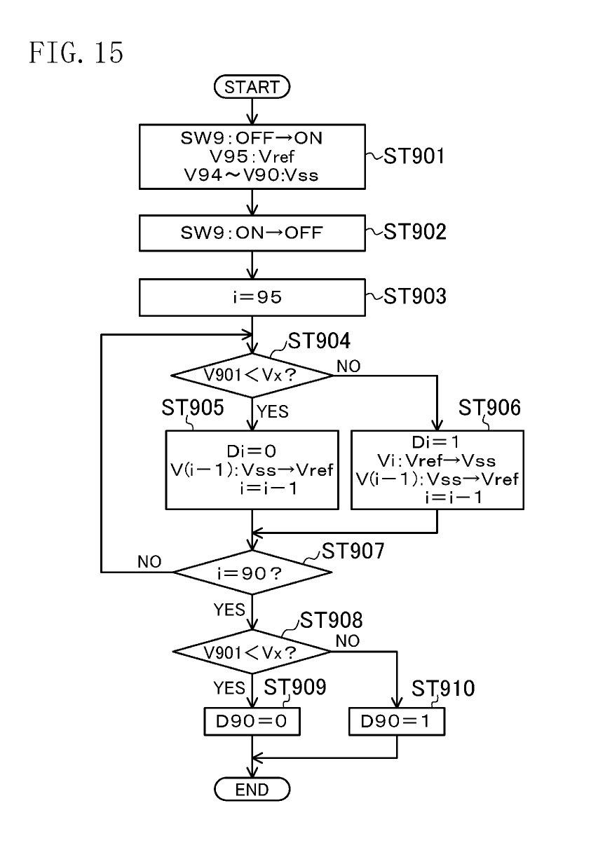

FIGS. 16A and 16B are diagrams for describing movement of charge.

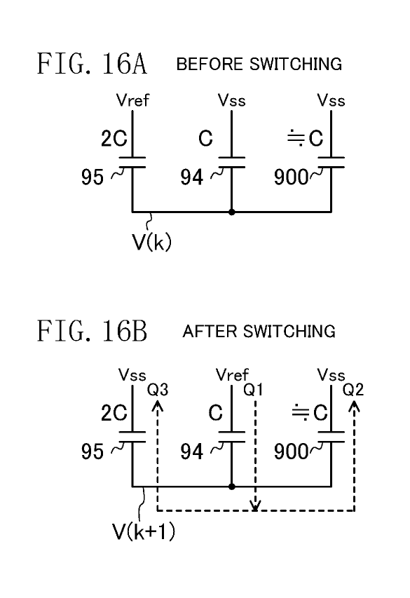

### DETAILED DESCRIPTION

Embodiments will be described hereinafter with reference to the accompanying drawings. Note that the same reference characters are used throughout the drawings to refer to the same or corresponding parts, which will not be redundantly described.

### First Embodiment

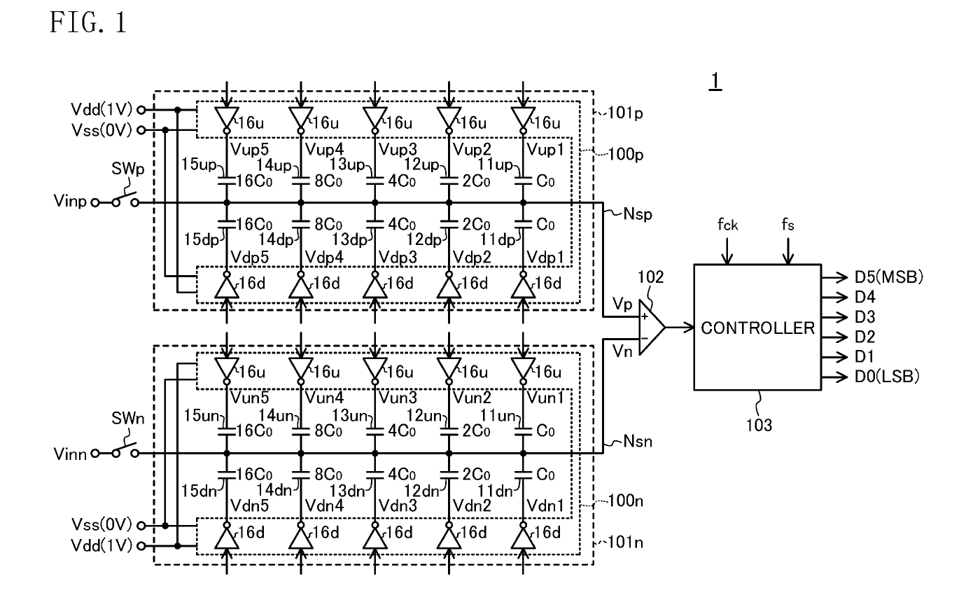

FIG. 1 shows an example configuration of a successive approximation AD converter 1 according to a first embodiment. The successive approximation AD converter 1 converts analog signals Vinp and Vinn whose voltage values are complementary to each other into a digital code including (n+1) (n≧2, here, n=5) bit values D5-D0. The successive approximation AD converter 1 includes capacitor DA converters 101p and 101n, sampling switches SWp and SWn, a comparator 102, and a controller 103.

[Capacitor DA Converter]

The capacitor DA converter 101p includes n (here, n=5) up-capacitors 15up-11up, n (here, n=5) down-capacitors 15dp-11dp, and a supply switch 100p. One ends of the up-capacitors 15up-11up are connected to a sampling node Nsp. The capacitance values of the up-capacitors 15up-11up are binary-weighted. For example, if the capacitance value of the up-capacitor 11up is C₀, the capacitance values of the up-capacitors 12up, 13up, 14up, and 15up are 2C₀, 4C₀, 8C₀, and 16C₀, respectively. The up-capacitors 15up-11up correspond to the bit values D5-D1, respectively, excluding the bit value D0 (the least significant bit (LSB) value). The down-capacitors 15dp-11dp have a configuration similar to that of the up-capacitors 15up-11up. The supply switch 100p supplies, in response to a control of the controller 103, one of a ground voltage Vss (e.g., 0 V) and a power supply voltage Vdd (e.g., 1 V) to the other ends of the up-capacitors 15up-11up and the down-capacitors 15dp-11dp. Here, the supply switch 100p includes n (here, n=5) inverters 16u-16u and n (here, n=5) inverters 16d-16d. The inverters 16u-16u and the inverters 16d-16d supply, in response to a control of the controller 103, one of the ground voltage Vss and the power supply voltage Vdd, as control voltages Vup5-Vup1 and control voltages Vdp5-Vdp1, to the other ends of the up-capacitors 15up-11up and the down-capacitors 15dp-11dp, respectively.

The capacitor DA converter 101n has a configuration similar to that of the capacitor DA converter 101p, i.e., includes n (here, n=5) up-capacitors 15un-11un, n (here, n=5) down-capacitors 15dn-11dn, and a supply switch 100n. One ends of the up-capacitors 15un-11un and the down-capacitors 15dn-11dn are connected to a sampling node Nsn. The supply switch 100n supplies, in response to a control of the controller 103, one of the ground voltage Vss and the power supply voltage Vdd to the other ends of the up-capacitors 15un-11un and the down-capacitors 15dn-11dn. In the capacitor DA converter 101n, the inverters 16u-16u and the inverters 16d-16d supply, in response to a control of the controller 103, one of the ground voltage Vss and the power supply voltage Vdd, as control voltages Vun5-Vun1 and control voltages Vdn5-Vdn1, to the other ends of the up-capacitors 15un-11un and the down-capacitors 15dn-11dn, respectively.

[Sampling Switch]

The sampling switches SWp and SWn are provided to sample the analog signals Vinp and Vinn for the sampling nodes Nsp and Nsn, respectively. The sampling switches SWp and SWn each switch between the on state and the off state in response to a control of the controller 103.

[Comparator]

The comparator 102 compares an analog voltage Vp at the sampling node Nsp with an analog voltage Vn at the sampling node Nsn. For example, the output of the comparator 102 is at a low level if the analog voltage Vp is lower than the analog voltage Vn and at a high level if the analog voltage Vp is not lower than the analog voltage Vn.

[Controller]

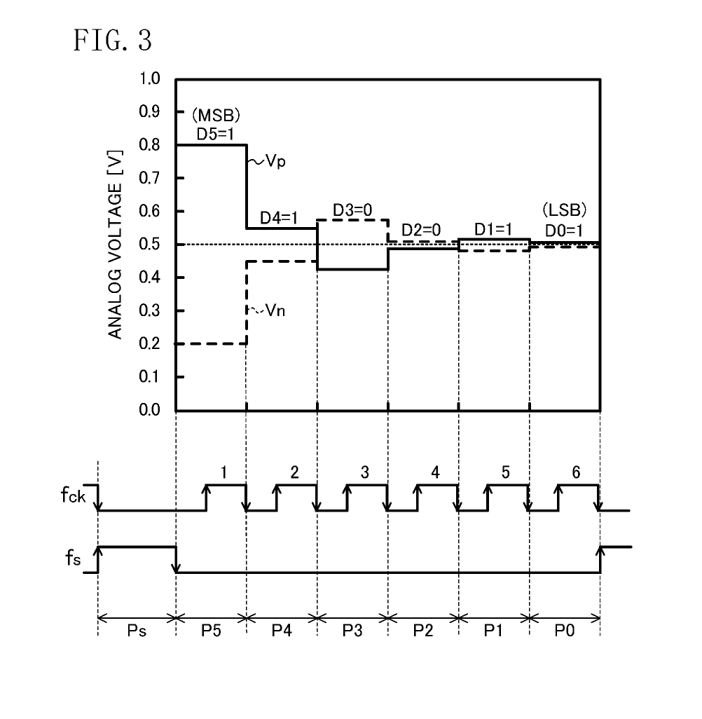

The controller 103 controls the sampling switches SWp and SWn and the supply switches 100p and 100n and determines the bit values D5-D0 in synchronization with the sampling clock fs and the internal clock fck. For example, as shown in FIG. 3, the internal clock fck has six pulses during one cycle of the sampling clock fs (specifically, a low-level period of the sampling clock fs). Here, a sampling period Ps is defined by a high-level period (a period of time from a rising edge to a falling edge) of the sampling clock fs, and n (here, n=5) bit determination periods P5-P1 are defined by the falling edge of the sampling clock fs and the first to fifth falling edges of the internal clock fck. A least significant bit determination period P0 is defined by the fifth falling edge of the internal clock fck and the rising edge of the sampling clock fs. The bit determination periods P5-P1 and the least significant bit determination period P0 correspond to the bit values D5-D1 and the bit value D0 (the least significant bit value), respectively.

The controller 103 controls the supply switches 100p and 100n so that, during the sampling period Ps, the ground voltage Vss is supplied to the other ends of the up-capacitors 15up-11up and the up-capacitors 15un-11un, and the power supply voltage Vdd is supplied to the other ends of the down-capacitors 15dp-11dp and the down-capacitors 15dn-11dn.

The controller 103 determines the bit values D5-D0 sequentially from the bit value D5 (the most significant bit (MSB) value). Specifically, during each of the bit determination periods P5-P1 and the least significant bit determination period P0, the controller 103 determines one corresponding to the bit determination period of the bit values D5-D0 based on the result of comparison by the comparator 102.

The controller 103 also controls the supply switches 100p and 100n based on the result of comparison by the comparator 102 during each of the bit determination periods P5-P1 so that the analog voltages Vp and Vn gradually approach each other. Specifically, during each of the bit determination periods P5-P1, if the analog voltage Vp is lower than the analog voltage Vn, the controller 103 controls the supply switches 100p and 100n so that the power supply voltage Vdd and the ground voltage Vss are supplied to the other ends of ones corresponding to the bit determination period of the up-capacitors 15up-11up and the down-capacitors 15dn-11dn, respectively, and if the analog voltage Vp is not lower than the analog voltage Vn, the controller 103 controls the supply switches 100p and 100n so that the ground voltage Vss and the power supply voltage Vdd are supplied to the other ends of ones corresponding to the bit determination period of the down-capacitors 15dp-11dp and the up-capacitors 15un-11un, respectively.

[Operation]

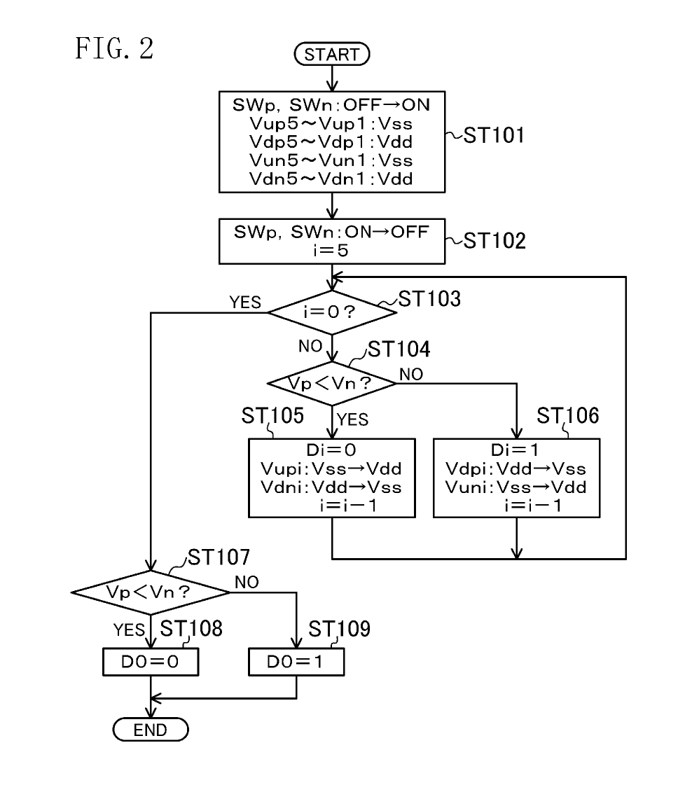

Next, operation of the successive approximation AD converter 1 will be described with reference to FIG. 2.

<<ST101>>

Initially, when the sampling period Ps begins, the controller 103 sets the control voltages Vup5-Vup1 and the control voltages Vun5-Vun1 to the ground voltage Vss, and the control voltages Vdp5-Vdp1 and the control voltages Vdn5-Vdn1 to the power supply voltage Vdd, and switches the sampling switches SWp and SWn from the off state to the on state.

<<ST102>>

Next, when the sampling period Ps ends, the controller 103 switches the sampling switches SWp and SWn from the on state to the off state. The controller 103 also selects the bit value D5 (the most significant bit value) of the six bit values D5-D0, as a bit value to be processed (hereinafter referred to as the bit value Di, here, i=5-0).

<<ST103>>

Next, the controller 103 determines whether or not the bit value Di is the bit value D0 (the least significant bit value). If the bit value Di is not the bit value D0, control proceeds to step ST104. If the bit value Di is the bit value D0, control proceeds to step ST107.

<<ST104>>

Next, during a bit determination period corresponding to the bit value Di (hereinafter referred to as a bit determination period Pi), the controller 103 determines whether or not the analog voltage Vp is lower than the analog voltage Vn, based on the result of comparison by the comparator 102. If the analog voltage Vp is lower than the analog voltage Vn, control proceeds to step ST105, and otherwise, control proceeds to step ST106.

<<ST105>>

If the analog voltage Vp is lower than the analog voltage Vn, the controller 103 determines that the bit value Di is “0.” The controller 103 also switches one corresponding to the bit determination period Pi (hereinafter referred to as a control voltage Vupi) of the control voltages Vup5-Vup1 from the ground voltage Vss to the power supply voltage Vdd, and one corresponding to the bit determination period Pi (hereinafter referred to as a control voltage Vdni) of the control voltages Vdn5-Vdn1 from the power supply voltage Vdd to the ground voltage Vss. Next, the controller 103 selects one succeeding the bit value Di of the bit values D5-D0 as the next target to be processed. Next, control proceeds to step ST103.

<<ST106>>

On the other hand, if the analog voltage Vp is not lower than the analog voltage Vn, the controller 103 determines that the bit value Di is “1.” The controller 103 also switches one corresponding to the bit determination period Pi (hereinafter referred to as a control voltage Vdpi) of the control voltages Vdp5-Vdp1 from the power supply voltage Vdd to the ground voltage Vss, and one corresponding to the bit determination period Pi (hereinafter referred to as a control voltage Vuni) of the control voltages Vun5-Vun1 from the ground voltage Vss to the power supply voltage Vdd. Next, the controller 103 selects one succeeding the bit value Di of the bit values D5-D0 as the next target to be processed. Next, control proceeds to step ST103.

<<ST107>>

If, in step ST103, the controller 103 determines that the bit value Di is the bit value D0 (the least significant bit value), during the least significant bit determination period P0 corresponding to the bit value D0 the controller 103 determines whether or not the analog voltage Vp is lower than the analog voltage Vn, based on the result of comparison by the comparator 102. If the analog voltage Vp is lower than the analog voltage Vn, control proceeds to step ST108, and otherwise, control proceeds to step ST109.

<<ST108, ST109>>

If the analog voltage Vp is lower than the analog voltage Vn, the controller 103 determines that the bit value D0 is “0” (ST108). On the other hand, if the analog voltage Vp is not lower than the analog voltage Vn, the controller 103 determines that the bit value D0 is “1” (ST109).

### Specific Example

Next, specific example operation of the successive approximation AD converter 1 will be described with reference to FIG. 3.

After the sampling period Ps has elapsed, the controller 103 determines that the bit value D5 is “1,” in synchronization with the first rising edge of the internal clock fck, during the bit determination period P5 (e.g., a period of time from the falling edge of the sampling clock fs to the first falling edge of the internal clock fck) corresponding to the bit value D5 (the most significant bit value). Next, in synchronization with the first falling edge of the internal clock fck, the controller 103 switches the control voltage Vdp5 corresponding to the bit determination period P5 from the power supply voltage Vdd to the ground voltage Vss, and the control voltage Vun5 corresponding to the bit determination period P5 from the ground voltage Vss to the power supply voltage Vdd. As a result, the analog voltage Vp decreases while the analog voltage Vn increases.

Next, during the bit determination period P4 (e.g., a period of time from the first falling edge to the second falling edge of the internal clock fck) corresponding to the bit value D4, the controller 103 determines that the bit value D4 is “1,” in synchronization with the second rising edge of the internal clock fck. Next, in synchronization with the second falling edge of the internal clock fck, the controller 103 switches the control voltage Vdp4 corresponding to the bit determination period P4 from the power supply voltage Vdd to the ground voltage Vss, and the control voltage Vun4 corresponding to the bit determination period P4 from the ground voltage Vss to the power supply voltage Vdd. As a result, the analog voltage Vp decreases while the analog voltage Vn increases.

Next, during the bit determination periods P3 and P2 corresponding to the bit values D3 and D2, the controller 103 determines that the bit values D3 and D2 are “0,” in synchronization with the third and fourth rising edges of the internal clock fck. Next, in synchronization with the third and fourth falling edges of the internal clock fck, the controller 103 switches the control voltages Vup3 and Vup2 corresponding to the bit determination periods P3 and P2 from the ground voltage Vss to the power supply voltage Vdd, and the control voltages Vdn3 and Vdn2 corresponding to the bit determination periods P3 and P2 from the power supply voltage Vdd to the ground voltage Vss. As a result, the analog voltage Vp increases while the analog voltage Vn decreases.

Next, during the bit determination period P1 corresponding to the bit value D1, the controller 103 determines that the bit value D1 is “1,” in synchronization with the fifth rising edge of the internal clock fck. Next, in synchronization with the fifth falling edge of the internal clock fck, the controller 103 switches the control voltage Vdp1 corresponding to the bit determination period P1 from the power supply voltage Vdd to the ground voltage Vss, and the control voltage Vun1 corresponding to the bit determination period P1 from the ground voltage Vss to the power supply voltage Vdd.

Next, during the least significant bit determination period P0 (e.g., a period of time from the fifth falling edge of the internal clock fck to the rising edge of the sampling clock fs) corresponding to the bit value D0, the controller 103 determines that the bit value D0 is “1,” in synchronization with the sixth rising edge of the internal clock fck.

[Movement of Charge]

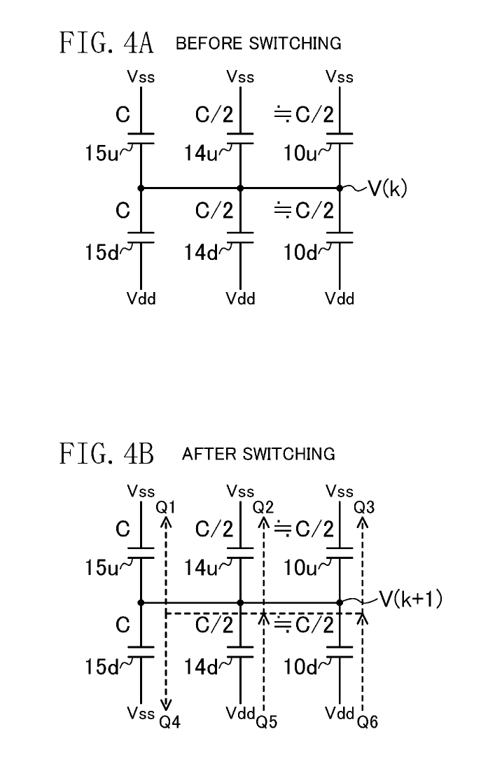

Next, movement of charge in the capacitor DA converters 101p and 101n of FIG. 1 will be described with reference to FIGS. 4A and 4B. Here, the capacitor DA converter 101p will be described as an example. Note that, in FIGS. 4A and 4B, up-capacitors 15u and 14u correspond to the up-capacitors 15up and 14up, respectively, an up-capacitor 10u corresponds to a combination (combined capacitor) of the up-capacitors 13up-11up, down-capacitors 15d and 14d correspond to the down-capacitors 15dp and 14dp, respectively, and a down-capacitor 10d corresponds to a combination (combined capacitor) of the down-capacitors 13dp-11dp. If the capacitance values of the capacitors 15u and 15d are C, the capacitance values of the capacitors 14u and 14d are C/2, and the capacitance values of the capacitors 10u and 10d are approximated by C/2.

In step ST102, as shown in FIG. 4A, the ground voltage Vss is applied to the other ends of the up-capacitors 15u, 14u, and 10u, and the power supply voltage Vdd is applied to the other ends of the down-capacitors 15d, 14d, and 10d. Next, if the analog voltage Vp is not lower than the analog voltage Vn, in step ST106 the control voltage applied to the other end of the down-capacitor 15d is switched from the power supply voltage Vdd to the ground voltage Vss. In this case, as shown in FIG. 4B, charges Q1, Q2, . . . , and Q6 move in the up-capacitors 15u, 14u, and 10u and the down-capacitors 15d, 14d, and 10d, respectively, i.e., charge is redistributed in the up-capacitors 15u, 14u, and 10u and the down-capacitors 15d, 14d, and 10d. The charges Q5 and Q6 which move in the down-capacitors 14d and 10d to which the power supply voltage Vdd is applied after the switching of the control voltage, correspond to charges consumed by the charge redistribution. The charges Q5 and Q6 are represented by:

$$\begin{matrix}\begin{matrix}Q 5 = ( C / 2 ) \{ Vref - V ( k + 1 ) \} - ( C / 2 ) \{ Vref - V ( k ) \} \\ = ( C / 2 ) \{ V ( k ) - V ( k + 1 ) \}\end{matrix} & ( 2 ) \\ \begin{matrix}Q 6 = ( C / 2 ) \{ Vref - V ( k + 1 ) \} - ( C / 2 ) \{ Vref - V ( k ) \} \\ = ( C / 2 ) \{ V ( k ) - V ( k + 1 ) \}\end{matrix} & ( 3 )\end{matrix}$$

where V(k) is the analog voltage Vp before the switching of the control voltage, and V(k+1) is the analog voltage Vp after the switching of the control voltage.

The sum of the charges Q5 and Q6 are represented by:

Q5+Q6=C{V(k)−V(k+1)} (4)

As can be seen from the above expression, the amount of charge moved in step ST106 (the amount of charge moved in the capacitor DA converter 101p) is smaller than the amount of charge moved in the conventional successive approximation AD converter (ST906) (by C·Vdd). Similarly, the amount of charge moved in step ST105 (the amount of charge moved in the capacitor DA converter 101n) is smaller than the amount of charge moved in the conventional successive approximation AD converter (ST906).

As described above, the capacitor array of the capacitor DA converter 101p is divided into an up-capacitor array (the up-capacitors 15up-11up) and a down-capacitor array (the down-capacitors 15dp-11dp). By controlling the up-capacitor array and the down-capacitor array separately, the power consumption of the capacitor DA converter 101p can be reduced. In a similar manner, the power consumption of the capacitor DA converter 101n can be reduced. As a result, the power consumption of the successive approximation AD converter 1 can be reduced.

Typically, in a semiconductor integrated circuit, the power supply voltage has the lowest impedance. Therefore, if the power supply voltage Vdd is applied to the other ends of the up-capacitors 15up-11up and the up-capacitors 15un-11un, the settling time can be reduced, compared to when a voltage having a higher impedance than that of the power supply voltage Vdd is applied to the other ends of the up-capacitors 15up-11up and the up-capacitors 15un-11un.

(First Variation of First Embodiment)

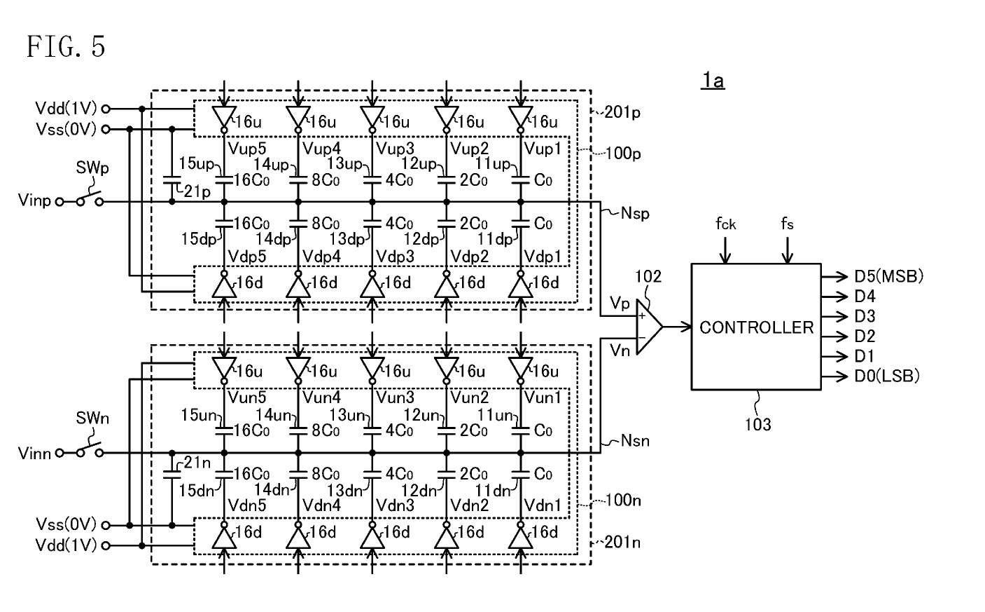

A successive approximation AD converter 1a shown in FIG. 5 includes capacitor DA converters 201p and 201n instead of the capacitor DA converters 101p and 101n of FIG. 1. In other respects, the configuration of the successive approximation AD converter 1a of FIG. 5 is similar to that of the successive approximation DA converter 1 of FIG. 1. The capacitor DA converters 201p and 201n include input capacitors 21p and 21n in addition to the components of the capacitor DA converters 101p and 101n of FIG. 1, respectively. The input capacitor 21p is connected between the sampling node Nsp and a ground node (a node to which the ground voltage Vss is applied). The input capacitor 21n is connected between the sampling node Nsn and the ground node. With this configuration, the input range of the successive approximation AD converter 1a can be adjusted. For example, the input range of the successive approximation AD converter 1a can be made narrower than that of the successive approximation AD converter 1 of FIG. 1. Specifically, if the capacitance values of the input capacitors 21p and 21n are 128C_{O3} the input range of the successive approximation AD converter 1a can be set to be 62/(62+128) times as wide as that of the successive approximation AD converter 1. As a result, for example, the input range of the successive approximation AD converter 1a can be accommodated within the linear range of a sampling buffer (not shown) which is provided in a preceding stage of the successive approximation AD converter 1a.

(Second Variation of First Embodiment)

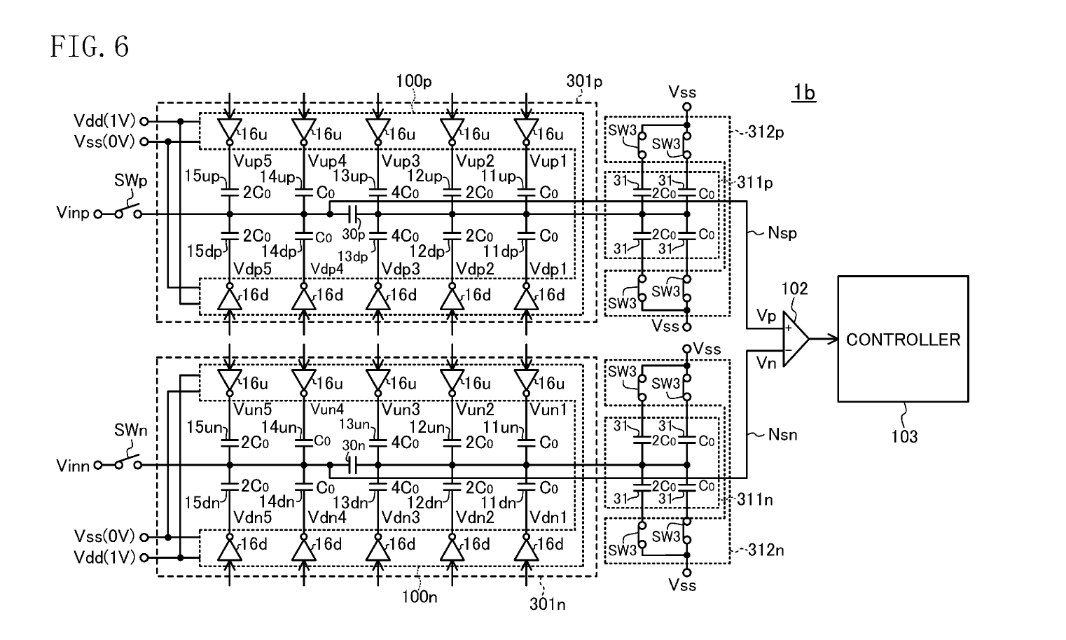

A successive approximation AD converter 1b shown in FIG. 6 includes series-parallel capacitor DA converters 301p and 301n instead of the capacitor DA converters 101p and 101n of FIG. 1. The successive approximation AD converter 1b further includes correction capacitor arrays 311p and 311n and capacitor correctors 312p and 312n. In other respects, the configuration of the successive approximation AD converter 1b is similar to that of the successive approximation AD converter 1 of FIG. 1.

[Capacitor DA Converter]

The capacitor DA converters 301p and 301n include coupling capacitors 30p and 30n in addition to the components of the capacitor DA converters 101p and 101n of FIG. 1, respectively.

One end of the coupling capacitor 30p is connected to one ends of p (here, p=2) up-capacitors 15up and 14up and p (here, p=2) down-capacitors 15dp and 14dp, and the sampling node Nsp. The other end of the coupling capacitor 30p is connected to one ends of q (p+q=n, here, q=3) up-capacitors 13up-11up and q (p+q=n, here, q=3) down-capacitors 13dp-11dp. In other words, the one ends of the up-capacitors 13up-11up and the down-capacitors 13dp-11dp are connected via the coupling capacitor 30p to the sampling node Nsp. Note that the p up-capacitors 15up and 14up and the p down-capacitors 15dp and 14dp correspond to the most significant p bits (here, the bit values D5 and D4) of the digital code, and the q up-capacitors 13up-11up and the q down-capacitors 13dp-11dp correspond to the least significant q bits (here, the bit values D3, D2, and D1) excluding the least significant bit of the digital code.

One end of the coupling capacitor 30n is connected to one ends of p (here, p=2) up-capacitors 15un and 14un and p (here, p=2) down-capacitors 15dn and 14dn, and the sampling node Nsn. The other end of the coupling capacitor 30n is connected to one ends of q (p+q=n, here, q=3) up-capacitors 13un-11un and q (p+q=n, here, q=3) down-capacitors 13dn-11dn. Specifically, the one ends of the up-capacitors 13un-11un and the down-capacitors 13dn-11dn are connected via the coupling capacitor 30n to the sampling node Nsn. Note that the p up-capacitors 15un and 14un and the p down-capacitors 15dn and 14dn correspond to the most significant p bits (here, the bit values D5 and D4) of the digital code, and the q up-capacitors 13un-11un and the q down-capacitors 13dn-11dn correspond to the least significant q bits (here, the bit values D3, D2, and D1) excluding the least significant bit of the digital code.

As described above, by configuring the capacitor DA converters 301p and 301n using a series-parallel capacitor array, the area where the capacitor DA converters are mounted can be reduced, compared to when a capacitor DA converter is configured using a series capacitor array (e.g., the capacitor DA converters 101p and 101n of FIG. 1). For example, if the capacitance values of the up-capacitor 11up and the down-capacitor 11dp are C₀, the capacitance values of the up-capacitor 15up and the down-capacitor 15dn are 2C₀, and the capacitance values of the up-capacitor 14up and the down-capacitor 14dn are C₀. Note that the capacitor DA converters 301p and 301n may further include the input capacitors 21p and 21n of FIG. 5, respectively.

[Correction Capacitor Array, Capacitor Corrector]

The correction capacitor array 311p includes a plurality of (here, four) correction capacitors 31-31. One ends of the correction capacitors 31-31 included in the correction capacitor array 311p are connected to the other end of the coupling capacitor 30p. The capacitor corrector 312p switches the connection states between the other ends of the correction capacitors 31-31 included in the correction capacitor array 311p, and a ground node (a node to which the ground voltage Vss is applied). For example, the capacitor corrector 312p includes a plurality of (here, four) switches SW3-SW3 which are connected between the other ends of the correction capacitors 31-31 included in the correction capacitor array 311p, and the ground node.

The correction capacitor array 311n includes a plurality of (here, four) correction capacitors 31-31. One ends of the correction capacitors 31-31 included in the correction capacitor array 311n are connected to the other ends of the coupling capacitor 30n. The capacitor corrector 312n switches the connection states between the other ends of the correction capacitors 31-31 included in the correction capacitor array 311n, and the ground node. For example, the capacitor corrector 312n includes a plurality of (here, four) switches SW3-SW3 which are connected between the other ends of the correction capacitors 31-31 included in the correction capacitor array 311n, and the ground node.

[Design of Coupling Capacitor and Correction of Capacitor]

Next, the design of the coupling capacitors 30p and 30n, and capacitor correction performed by using the correction capacitor arrays 311p and 311n and the capacitor correctors 312p and 312n, will be described. Here, the capacitor DA converter 301p will be described as an example.

Firstly, the total capacitance value C_{T1} of the upper capacitor array and the total capacitance value C_{T2} of the lower capacitor array are represented by:

$$\begin{matrix}{C}_{T 1} = {\sum }_{x = 1}^{p} {2}^{x} {C}_{u 1} + {C}_{p 1} & ( 5 ) \\ {C}_{T 2} = {\sum }_{y = 1}^{q} {2}^{y} {C}_{u 2} + {C}_{p 2} + {C}_{trim} & ( 6 )\end{matrix}$$

where Cᵤ₁ is the unit capacitance of the upper capacitor array (the up-capacitors 15up and 14up and the down-capacitors 15dp and 14dp), Cₚ₁ is a parasitic capacitance added to a common electrode of the upper capacitor array, Cᵤ₂ is the unit capacitance of the lower capacitor array (the up-capacitors 13up-11up and the down-capacitors 13dp-11dp), Cₚ₂ is a parasitic capacitance added to a common electrode of the lower capacitor array, and Cₜᵣᵢₘ is the capacitance value of the correction capacitor array 311p (the total capacitance value of one or some of the correction capacitors 31-31 the other ends of which are connected to the ground node).

The capacitance value C_{eq1} of an equivalent capacitor including the upper capacitor array and the coupling capacitor 30p, and the capacitance value C_{eq2} of an equivalent capacitor including the coupling capacitor 30p and the lower capacitor array, are represented by:

$$\begin{matrix}{C}_{eq 1} = {C}_{a} \vert \vert {C}_{T 1} = \frac{{C}_{a} {C}_{T 1}}{{C}_{a} + {C}_{T 1}} & ( 7 ) \\ {C}_{eq 2} = {C}_{a} \vert \vert {C}_{T 2} = \frac{{C}_{a} {C}_{T 2}}{{C}_{a} + {C}_{T 2}} & ( 8 )\end{matrix}$$

where Cₐ is the capacitance value of the coupling capacitor 30p, and “∥” indicates that the upper capacitor array and the coupling capacitor 30p (or the coupling capacitor 30p and the lower capacitor array) are connected together in series.

A voltage change (a voltage change of the sampling node Nsp) ΔV₁ with respect to a unit charge amount (Cᵤ₁·V_{dd}) of the upper capacitor array is represented by:

$$Δ {V}_{1} = \frac{{C}_{u 1}}{{C}_{T 1} + {C}_{eq 2}} {V}_{dd} \qquad ( 9 )$$

The voltage change ΔV₁ is converted into a voltage change ΔV₁′ which occurs in the unit capacitance of the lower capacitor array. The voltage change ΔV₁′ is represented by:

$$Δ {V}_{1}^{′} = \frac{1}{{2}^{q}} Δ {V}_{1} = \frac{1}{{2}^{q}} \frac{{C}_{u 1}}{{C}_{T 1} + {C}_{eq 2}} {V}_{dd} \qquad ( 10 )$$

On the other hand, a voltage change ΔV₂ with respect to a unit charge amount (Cᵤ₂·V_{dd}) of the lower capacitor array is represented by:

$$Δ {V}_{2} = \frac{{C}_{u 2}}{{C}_{T 2} + {C}_{eq 1}} {V}_{dd} \qquad ( 11 )$$

The voltage change ΔV₂ is converted into a voltage change ΔV₂′ (a voltage change of the sampling node Nsp) which occurs in the upper capacitor array. The voltage change ΔV₂′ is represented by:

$$Δ {V}_{2}^{′} = Δ {V}_{2} = \frac{{C}_{a}}{{C}_{T 1} + {C}_{a}} = \frac{{C}_{u 2}}{{C}_{T 2} + {C}_{eq 1}} {V}_{dd} \frac{{C}_{a}}{{C}_{T 1} + {C}_{a}} \qquad ( 12 )$$

Here, the voltage change ΔV₁′ and the voltage change ΔV₂′ are equal to each other, and therefore, the following relationship is established:

ΔV₁′=ΔV₂′ (13)

Next, if the expressions 10 and 12 are substituted into the expression 13, the following expression is obtained:

$$\frac{1}{{2}^{q}} \frac{{C}_{u 1}}{{C}_{T 1} + {C}_{eq 2}} {V}_{dd} = \frac{{C}_{u 2}}{{C}_{T 2} + {C}_{eq 1}} {V}_{dd} \frac{{C}_{a}}{{C}_{T 1} + {C}_{a}} \qquad ( 14 )$$

The above expression is rearranged into the following form:

$$\frac{{C}_{u 2}}{{C}_{u 1}} \frac{{C}_{a}}{{C}_{T 1} + {C}_{a}} = \frac{1}{{2}^{q}} \frac{{C}_{T 2} + {C}_{eq 1}}{{C}_{T 1} + {C}_{eq 2}} \qquad ( 15 )$$

Next, if the expressions 7 and 8 are substituted into the expression 15, the following expression is obtained:

$$\frac{{C}_{u 2}}{{C}_{u 1}} \frac{{C}_{a}}{{C}_{T 1} + {C}_{a}} = \frac{1}{{2}^{q}} \frac{{C}_{T 2} + \frac{{C}_{a} {C}_{T 1}}{{C}_{a} + {C}_{T 1}}}{{C}_{T 1} + \frac{{C}_{a} {C}_{T 2}}{{C}_{a} + {C}_{T 2}}} \qquad ( 16 )$$

The above expression is rearranged to obtain the capacitance value Cₐ of the coupling capacitor 30p:

$${C}_{a} = \frac{{C}_{T 2}}{{2}^{q} \frac{{C}_{u 2}}{{C}_{u 1}} - 1} \qquad ( 17 )$$

If the capacitance value Cₐ of the coupling capacitor 30p is designed to be 1/{2^{q}(Cᵤ₂/Cᵤ₁)−1} as large as the total capacitance value C_{T2} of the lower capacitor array based on the above expression, the voltage change of the lower capacitor array can be equivalently converted into the voltage change of the sampling node Nsp by the coupling capacitor 30p, and therefore, the linearity of the capacitor DA converter 301p can be maintained.

In particular, if the unit capacitances of the upper and lower capacitor arrays are designed to be equal to each other (Cᵤ₁=Cᵤ₂=C₀), the following expression is obtained:

$${C}_{a} = \frac{{C}_{T 2}}{{2}^{q} - 1} \qquad ( 18 )$$

Specifically, if q=1-5, the following expression is obtained (q=3 in the example of FIG. 6):

Cₐ=C_{T2}/(2¹−1)=(2C₀+Cₚ₂+Cₜᵣᵢₘ)/1 when q=1

Cₐ=C_{T2}/(2²−1)=(6C₀+Cₚ₂+Cₜᵣᵢₘ)/3 when q=2

Cₐ=C_{T2}/(2³−1)=(14C₀+Cₚ₂+Cₜᵣᵢₘ)/7 when q=3

Cₐ=C_{T2}/(2⁴−1)=(30C₀+Cₚ₂+Cₜᵣᵢₘ)/15 when q=4

Cₐ=C_{T2}/(2⁵−1)=(62C₀+Cₚ₂+Cₜᵣᵢₘ)/31 when q=5 (19)

Here, if the parasitic capacitance Cₚ₂ of the lower capacitor array is sufficiently small, i.e., substantially zero, and the capacitance value Cₜᵣᵢₘ of the correction capacitor array is zero, the capacitance value Cₐ of the coupling capacitor 30p is invariably 2C₀ irrespective of the value of q. Note that, actually, a parasitic capacitance is added to each of the upper and lower capacitor arrays, and therefore, by controlling the connection state of the correction capacitor array 311p using the capacitor corrector 312p so that the expression 18 is established and thereby correcting the total capacitance value C_{T2} of the lower capacitor array, the linearity of the capacitor DA converter 301p can be maintained. In a similar manner, the linearity of the capacitor DA converter 301n can be maintained. As a result, the linearity of the successive approximation AD converter 1b can be improved.

Note that the successive approximation AD converter 1b may not include the correction capacitor arrays 311p and 311n and the capacitor correctors 312p and 312n.

(Third Variation of First Embodiment)

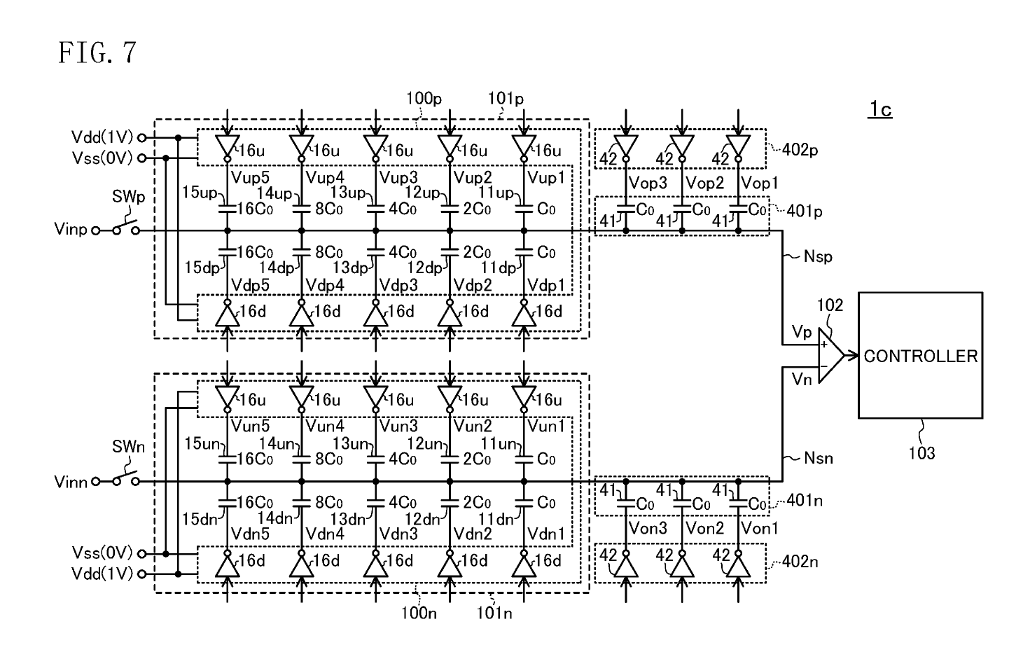

A successive approximation AD converter 1c shown in FIG. 7 includes offset adjustment capacitor arrays 401p and 401n and offset adjusters 402p and 402n in addition to the components of the successive approximation AD converter 1 of FIG. 1.

The offset adjustment capacitor array 401p includes a plurality of (here, three) offset adjustment capacitors 41-41. One ends of the offset adjustment capacitors 41-41 included in the offset adjustment capacitor array 401p are connected to the sampling node Nsp. The offset adjuster 402p supplies, in response to an external control, one of the ground voltage Vss and the power supply voltage Vdd to the other ends of the offset adjustment capacitors 41-41 included in the offset adjustment capacitor array 401p. For example, the offset adjuster 402p includes a plurality of (here, three) inverters 42-42. The inverters 42-42 each supply, in response to an external control, one of the ground voltage Vss and the power supply voltage Vdd, as offset control voltages Vop1-Vop3, to the other ends of the offset adjustment capacitors 41-41. For example, immediately after sampling, the inverters 42-42 each execute, in response to an external control, one of the operation of switching the offset control voltages Vop1-Vop3 from the ground voltage Vss to the power supply voltage Vdd (or from the power supply voltage Vdd to the ground voltage Vss) and the operation of not changing the offset voltages Vop1-Vop3.

The offset adjustment capacitor array 401n includes a plurality of (here, three) offset adjustment capacitors 41-41. One ends of the offset adjustment capacitors 41-41 included in the offset capacitor array 401n are connected to the sampling node Nsn. The offset adjuster 402n supplies, in response to an external control, one of the ground voltage Vss and the power supply voltage Vdd to the other ends of the offset adjustment capacitors 41-41 included in the offset capacitor array 401n For example, the offset adjuster 402n includes a plurality of (here, three) inverters 42-42. The inverters 42-42 each supply, in response to an external control, one of the ground voltage Vss and the power supply voltage Vdd, as offset control voltages Von1-Von3, to the other ends of the offset adjustment capacitors 41-41. For example, immediately after sampling, the inverters 42-42 each execute, in response to an external control, one of the operation of switching the offset control voltages Von1-Von3 from the ground voltage Vss to the power supply voltage Vdd (or from the power supply voltage Vdd to the ground voltage Vss) and the operation of not changing the offset voltages Von1-Von3.

With the above configuration, the offset of the comparator 102 can be adjusted (e.g., to zero). As a result, the offset of the successive approximation AD converter 1c can be adjusted (e.g., to zero). The offset adjustment capacitor arrays 401p and 401n and the offset adjusters 402p and 402n may be used to correct a mismatch in weighted capacitors (up-capacitors and down-capacitors) included in the capacitor DA converters 101p and 101n.

Note that the offset adjustment capacitors 41-41 included in the offset adjustment capacitor arrays 401p and 401n may all have the same capacitance value or weighted capacitance values.

The successive approximation AD converter 1c may include the capacitor DA converters 201p and 201n of FIG. 5 instead of the capacitor DA converters 101p and 101n.

(Fourth Variation of First Embodiment)

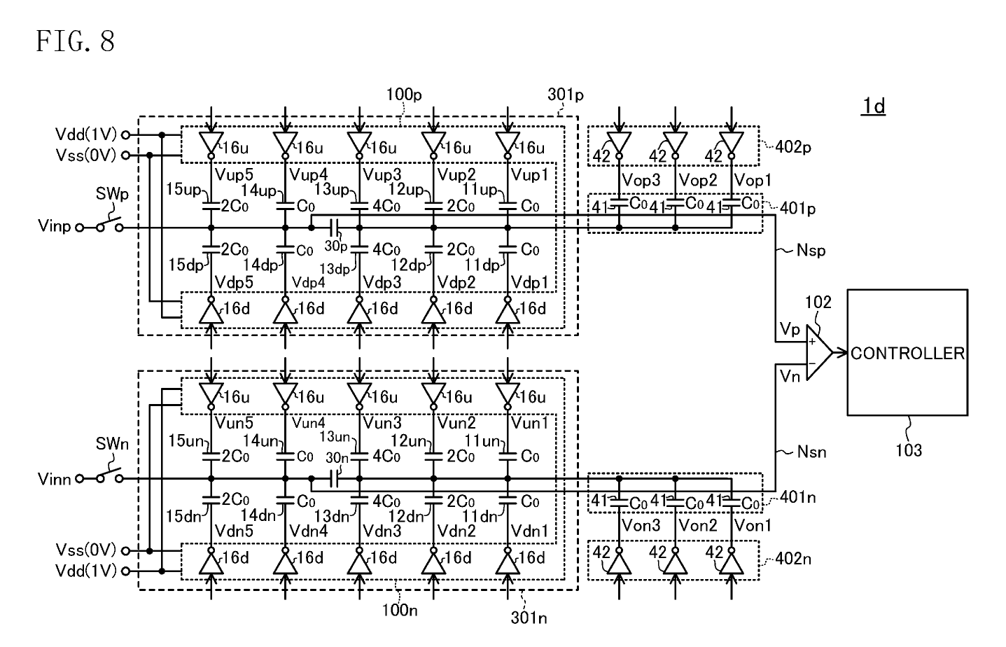

A successive approximation AD converter 1d shown in FIG. 8 includes offset adjustment capacitor arrays 401p and 401n and offset adjusters 402p and 402n instead of the correction capacitor arrays 311p and 311n and the capacitor correctors 312p and 312n of FIG. 6. In other respects, the configuration of the successive approximation AD converter 1d of FIG. 8 is similar to that of the successive approximation AD converter 1b of FIG. 6. One ends of offset adjustment capacitors 41-41 included in the offset adjustment capacitor array 401p are connected to the sampling node Nsp, and one ends of offset adjustment capacitors 41-41 included in the offset adjustment capacitor array 401n are connected to the sampling node Nsn. With this configuration, the offset of the comparator 102 can be adjusted (e.g., to zero). As a result, the offset of the successive approximation AD converter 1c can be adjusted (e.g., to zero). The offset adjustment capacitor arrays 401p and 401n and the offset adjusters 402p and 402n may be used to correct a mismatch in weighted capacitors (up-capacitors and down-capacitors) included in the capacitor DA converters 301p and 301n, or correct the capacitance values of the coupling capacitors 30p and 30n.

Note that the successive approximation AD converter 1d may further include the correction capacitor arrays 311p and 311n and the capacitor correctors 312p and 312n of FIG. 6.

### Second Embodiment

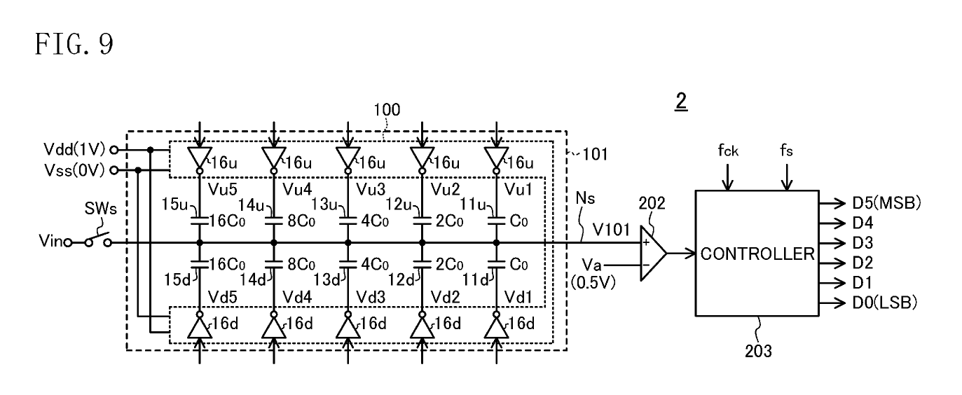

FIG. 9 shows an example configuration of a successive approximation AD converter 2 according to a second embodiment. The successive approximation AD converter 2 converts an analog signal Vin into a digital code including (n+1) (n≧2, here n=5) bit values D5-D0. The successive approximation AD converter 2 includes a capacitor DA converter 101, a sampling switch SWs, a comparator 202, and a controller 203.

[Capacitor DA Converter]

The capacitor DA converter 101 has a configuration similar to that of the capacitor DA converter 101p of FIG. 1. The capacitor DA converter 101 includes n (here, n=5) up-capacitors 15u-11u, n (here, n=5) down-capacitors 15d-11d, and a supply switch 100. One ends of the up-capacitors 15u-11u and the down-capacitors 15d-11d are connected to a sampling node Ns. The supply switch 100 supplies, in response to a control of the controller 203, one of a ground voltage Vss and a power supply voltage Vdd to the other ends of the up-capacitors 15u-11u and the down-capacitors 15d-11d. In the capacitor DA converter 101, inverters 16u-16u and inverters 16d-16d supply, in response to a control of the controller 203, one of the ground voltage Vss and power supply voltage Vdd as control voltages Vu5-Vu1 and control voltages Vd5-Vd1 to the other ends of the up-capacitors 15u-11u and the down-capacitors 15d-11d, respectively.

[Sampling Switch]

The sampling switch SWs is provided to sample the analog signal Vin for the sampling node Ns. The sampling switch SWs switches between the on state and the off state in response to a control of the controller 203.

[Comparator]

The comparator 202 compares an analog voltage V101 at the sampling node Ns with a comparative voltage Va (e.g., 0.5 V). For example, the output of the comparator 202 is at a low level if the analog voltage V101 is lower than the comparative voltage Va and at a high level if the analog voltage V101 is not lower than the comparative voltage Va.

[Controller]

The controller 203 controls the sampling switch SWs and the supply switch 100 and determines the bit values D5-D0 in synchronization with a sampling clock fs and an internal clock fck.

The controller 203 controls the supply switch 100 so that, during the sampling period Ps (see FIG. 3), the ground voltage Vss is supplied to the other ends of the up-capacitors 15u-11u, and the power supply voltage Vdd is supplied to the other ends of the down-capacitors 15d-11d.

The controller 203 determines the bit values D5-D0 sequentially from the bit value D5 (the most significant bit (MSB) value). Specifically, during each of the bit determination periods P5-P1 and the least significant bit determination period P0 (see FIG. 3), the controller 203 determines one corresponding to the bit determination period of the bit values D5-D0 based on the result of comparison by the comparator 202.

The controller 203 also controls the supply switch 100 based on the result of comparison by the comparator 202 during each of the bit determination periods P5-P1 so that the analog voltage V101 gradually approaches the comparative voltage Va. Specifically, during each of the bit determination periods P5-P1, if the analog voltage V101 is lower than the comparative voltage Va, the controller 203 controls the supply switch 100 so that the power supply voltage Vdd is supplied to the other end of one corresponding to the bit determination period of the up-capacitors 15u-11u, and if the analog voltage V101 is not lower than the comparative voltage Va, the controller 203 controls the supply switch 100 so that the ground voltage Vss is supplied to the other end of one corresponding to the bit determination period of the down-capacitors 15d-11d.

[Operation]

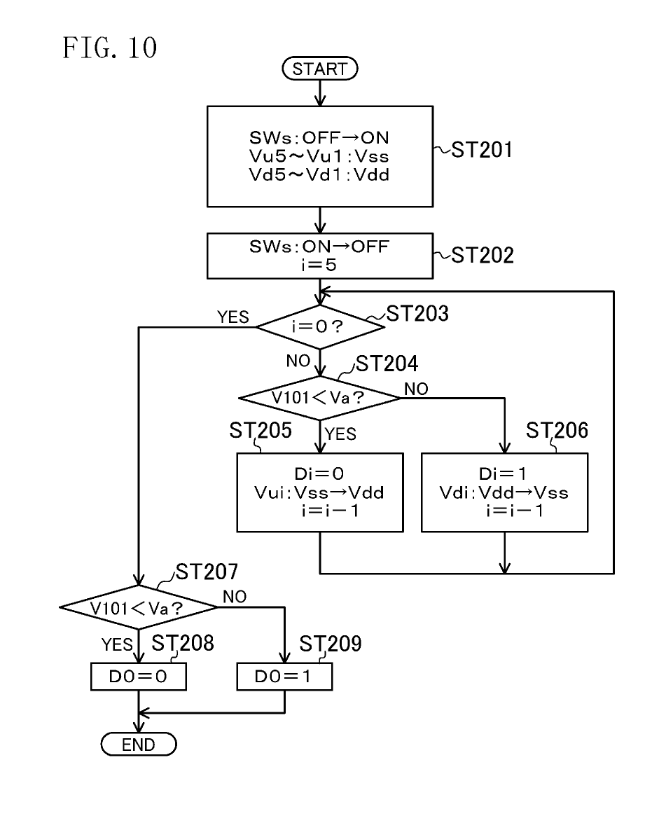

Next, operation of the successive approximation AD converter 2 will be described with reference to FIG. 10.

<<ST201>>

Initially, when the sampling period Ps begins, the controller 203 sets the control voltages Vu5-Vu1 to the ground voltage Vss, and the control voltages Vd5-Vd1 to the power supply voltage Vdd, and switches the sampling switch SWs from the off state to the on state.

<<ST202>>

Next, when the sampling period Ps ends, the controller 203 switches the sampling switch SWs from the on state to the off state. The controller 203 selects the bit value D5 (the most significant bit value) of the six bit values D5-D0, as a bit value to be processed (hereinafter referred to as the bit value Di, here, i=5-0).

<<ST203>>

Next, the controller 203 determines whether or not the bit value Di is the bit value D0 (the least significant bit value). If the bit value Di is not the bit value D0, control proceeds to step ST204. If the bit value Di is the bit value D0, control proceeds to step ST207.

<<ST204>>

Next, during a bit determination period corresponding to the bit value Di (hereinafter referred to as a bit determination period Pi), the controller 203 determines whether or not the analog voltage V101 is lower than the comparative voltage Va, based on the result of comparison by the comparator 202. If the analog voltage V101 is lower than the comparative voltage Va, control proceeds to step ST205, and otherwise, control proceeds to step ST206.

<<ST205>>

If the analog voltage V101 is lower than the comparative voltage Va, the controller 203 determines that the bit value Di is “0.” The controller 203 also switches one corresponding to the bit determination period Pi (hereinafter referred to as a control voltage Vui) of the control voltages Vu5-Vu1 from the ground voltage Vss to the power supply voltage Vdd. Next, the controller 203 selects one succeeding the bit value Di of the bit values D5-D0 as the next target to be processed. Next, control proceeds to step ST203.

<<ST206>>

On the other hand, if the analog voltage V101 is not lower than the comparative voltage Va, the controller 203 determines that the bit value Di is “1.” The controller 203 also switches one corresponding to the bit determination period Pi (hereinafter referred to as a control voltage Vdi) of the control voltages Vd5-Vd1 from the power supply voltage Vdd to the ground voltage Vss. Next, the controller 203 selects one succeeding the bit value Di of the bit values D5-D0 as the next target to be processed. Next, control proceeds to step ST203.

<<ST207>>

If, in step ST203, the controller 203 determines that the bit value Di is the bit value D0 (the least significant bit value), during the least significant bit determination period P0 corresponding to the bit value D0 the controller 203 determines whether or not the analog voltage V101 is lower than the comparative voltage Va, based on the result of comparison by the comparator 202. If the analog voltage V101 is lower than the comparative voltage Va, control proceeds to step ST208, and otherwise, control proceeds to step ST209.

<<ST208, ST209>>

If the analog voltage V101 is lower than the comparative voltage Va, the controller 203 determines that the bit value D0 is “0” (ST208). On the other hand, if the analog voltage V101 is not lower than the comparative voltage Va, the controller 203 determines that the bit value D0 is “1” (ST209).

As described above, the capacitor array of the capacitor DA converter 101 is divided into an up-capacitor array (the up-capacitors 15u-11u) and a down-capacitor array (the down-capacitors 15d-11d). By controlling the up-capacitor array and the down-capacitor array separately, the power consumption of the capacitor DA converter 101 can be reduced. As a result, the power consumption of the successive approximation AD converter 2 can be reduced.

Typically, in a semiconductor integrated circuit, the power supply voltage has the lowest impedance. Therefore, if the power supply voltage Vdd is applied to the other ends of the up-capacitors 15u-11u, the settling time can be reduced, compared to when a voltage having a higher impedance than that of the power supply voltage Vdd is applied to the other ends of the up-capacitors 15u-11u.

(First Variation of Second Embodiment)

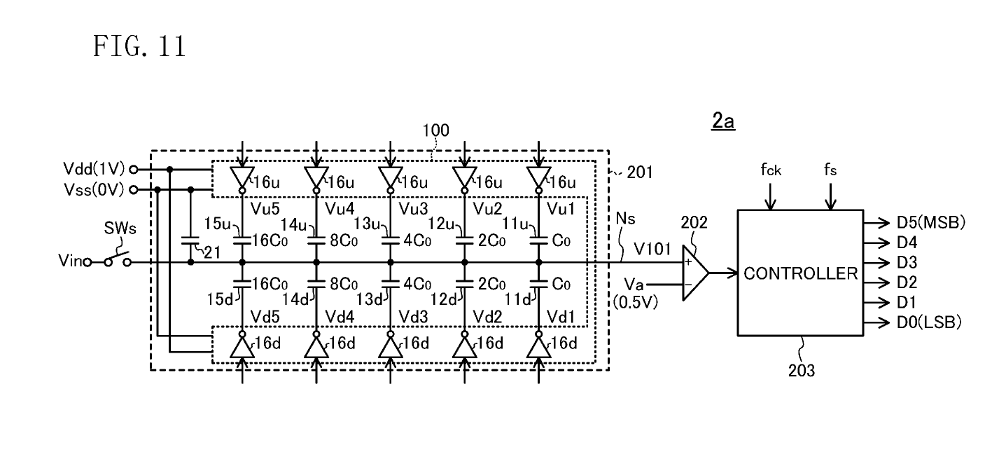

A successive approximation AD converter 2a shown in FIG. 11 includes a capacitor DA converter 201 instead of the capacitor DA converter 101 of FIG. 9. In other respects, the configuration of the successive approximation AD converter 2a of FIG. 11 is similar to that of the successive approximation DA converter 2 of FIG. 9. The capacitor DA converter 201 includes an input capacitor 21 connected between the sampling node Ns and a ground node (a node to which the ground voltage Vss is applied), in addition to the components of the capacitor DA converter 101 of FIG. 9. With this configuration, the input range of the successive approximation AD converter 2a can be made narrower than that of the successive approximation AD converter 2 of FIG. 9. For example, if the capacitance value of the input capacitor 21 is 128C₀, the input range of the successive approximation AD converter 2a can be set to be 62/(62+128) times as wide as that of the successive approximation AD converter 2. As a result, for example, the input range of the successive approximation AD converter 2a can be accommodated within the linear range of a sampling buffer (not shown) which is provided in a preceding stage of the successive approximation AD converter 2a.

(Second Variation of Second Embodiment)

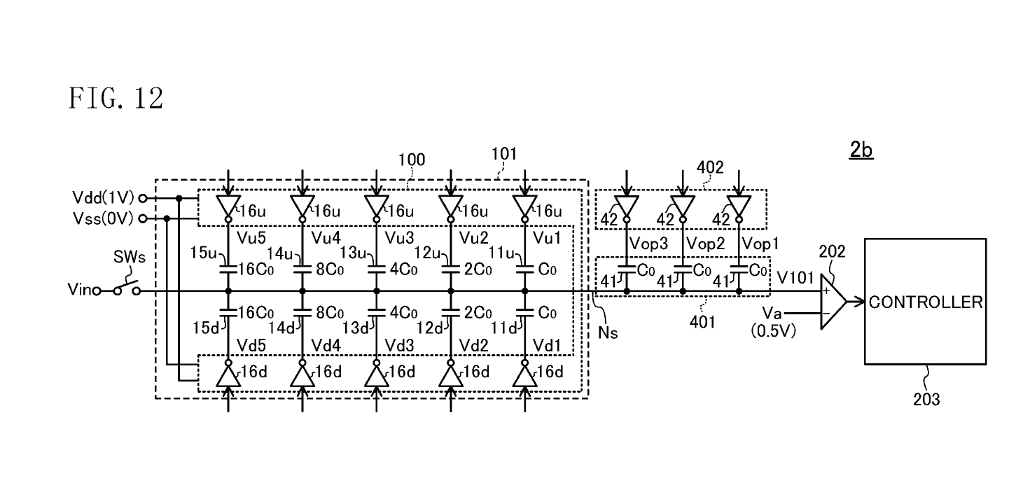

A successive approximation AD converter 2b shown in FIG. 12 includes an offset adjustment capacitor array 401 and an offset adjuster 402 in addition to the components of the successive approximation AD converter 2 of FIG. 9. The offset adjustment capacitor array 401 includes a plurality of (here, three) offset adjustment capacitors 41-41. One ends of the offset adjustment capacitors 41-41 are connected to the sampling node Ns. The offset adjuster 402 supplies, in response to an external control, one of the ground voltage Vss and the power supply voltage Vdd to the other ends of the offset adjustment capacitors 41-41. For example, the offset adjuster 402 includes a plurality of (here, three) inverters 42-42. The inverters 42-42 each supply, in response to an external control, one of the ground voltage Vss and the power supply voltage Vdd, as offset control voltages Vop1-Vop3, to the other ends of the offset adjustment capacitors 41-41. For example, immediately after sampling, the inverters 42-42 each execute, in response to an external control, one of the operation of switching the offset control voltages Vop1-Vop3 from the ground voltage Vss to the power supply voltage Vdd (or from the power supply voltage Vdd to the ground voltage Vss) and the operation of not changing the offset voltages Vop1-Vop3. With this configuration, the offset of the comparator 202 can be adjusted (e.g., to zero), so that the offset of the successive approximation AD converter 2b can be adjusted (e.g., to zero). The offset adjustment capacitor array 401 and the offset adjuster 402 may be used to correct a mismatch in weighted capacitors (up-capacitors and down-capacitors) included in the capacitor DA converter 101.

(Mobile Wireless Device)

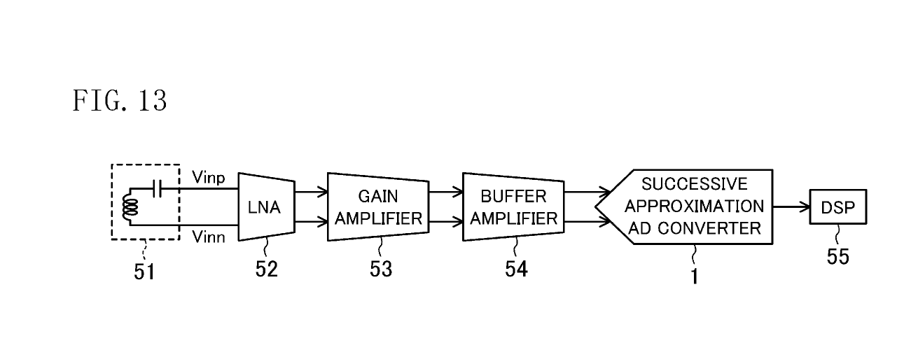

As shown in FIG. 13, the successive approximation AD converters 1, 1a, 1b, 1c, and 1d are applicable to a mobile wireless device. The mobile wireless device of FIG. 13 includes, in addition to the successive approximation AD converter 1, an antenna 51 (receiver), a low noise amplifier (LNA) 52, a gain amplifier 53, a buffer amplifier 54, and a digital signal processing circuit (DSP) 55.

The antenna 51 receives a wireless signal, and outputs a pair of analog signals Vinp and Vinn (weak analog signals). The low noise amplifier 52 amplifies the analog signals Vinp and Vinn while adding as little noise as possible. The gain amplifier 53 further amplifies the analog signals Vinp and Vinn which have been amplified by the low noise amplifier 52. The buffer amplifier 54 changes the output impedance to the successive approximation AD converter 1. The successive approximation AD converter 1 converts the analog signals Vinp and Vinn which have been supplied from the antenna 51 via the low noise amplifier 52, the gain amplifier 53, and the buffer amplifier 54, into a digital code. The digital signal processing circuit 55 processes the digital code which has been obtained by the successive approximation AD converter 1.

As described above, by applying a successive approximation AD converter whose power consumption can be reduced to a mobile wireless device, the power consumption of the mobile wireless device can be reduced. As a result, the life of a battery included in the mobile wireless device can be extended, i.e., the mobile wireless device can be used for a longer time.

Note that the successive approximation AD converters 2, 2a, and 2b are also applicable to a mobile wireless device. For example, if the successive approximation AD converter 2 is applied to the mobile wireless device of FIG. 13, an antenna 51 receives a wireless signal and outputs a single analog signal, and the successive approximation AD converter 2 converts the single analog signal which has been supplied from the antenna 51 via a low-noise amplifier 52, a gain amplifier 53, and a buffer amplifier 54, into a digital code.

As described above, in the above successive approximation AD converters, the power consumption can be reduced. Therefore, the successive approximation AD converters are useful for products for which a reduction in power consumption is demanded (e.g., mobile wireless devices) etc.

Note that the above embodiments are merely preferred examples in nature and are not intended to limit the present disclosure, application, or uses.

What is claimed is:

1. A successive approximation AD converter for converting first and second analog signals whose voltage values are complementary to each other into a digital code including (n+1) bit values, where n≧2, comprising:
a first capacitor DA converter including n first up-capacitors and n first down-capacitors each having a binary-weighted capacitance value, one ends of the n first up-capacitors and the n first down-capacitors being connected to a first sampling node, and a first supply switch configured to supply one of a ground voltage and a power supply voltage to the other ends of the n first up-capacitors and the n first down-capacitors;
a second capacitor DA converter including n second up-capacitors and n second down-capacitors each having a binary-weighted capacitance value, one ends of the n second up-capacitors and the n second down-capacitors being connected to a second sampling node, and a second supply switch configured to supply one of the ground voltage and the power supply voltage to the other ends of the n second up-capacitors and the n second down-capacitors;
first and second sampling switches configured to sample the first and second analog signals for the first and second sampling nodes, respectively, during a sampling period;
a comparator configured to compare a first analog voltage at the first sampling node with a second analog voltage at the second sampling node; and
a controller configured to control the first and second supply switches so that, during the sampling period, the ground voltage is supplied to the other ends of the n first up-capacitors and the n second up-capacitors while the power supply voltage is supplied to the other ends of the n first down-capacitors and the n second down-capacitors, determine the (n+1) bit values sequentially from a most significant bit value by determining, during each of n bit determination periods corresponding to the n bit values excluding a least significant bit value of the (n+1) bit values and a least significant bit determination period corresponding to the least significant bit value, one corresponding to the bit determination period of the (n+1) bit values based on a result of comparison by the comparator, and control the first and second supply switches based on the result of comparison by the comparator during each of the n bit determination periods so that the first and second analog voltages gradually approach each other.

2. The successive approximation AD converter of claim 1, wherein
during each of the n bit determination periods, if the first analog voltage is lower than the second analog voltage, the controller controls the first and second supply switches so that the power supply voltage and the ground voltage are supplied to ones corresponding to the bit determination period of the n first up-capacitors and the n second down-capacitors, respectively, and if the first analog voltage is not lower than the second analog voltage, the controller controls the first and second supply switches so that the ground voltage and the power supply voltage are supplied to ones corresponding to the bit determination period of the n first up-capacitors and the n second down-capacitors, respectively.

3. The successive approximation AD converter of claim 1, wherein
the first capacitor DA converter further includes a first input capacitor connected between the first sampling node and a ground node to which the ground voltage is applied, and
the second capacitor DA converter further includes a second input capacitor connected between the second sampling node and the ground node.

4. The successive approximation AD converter of claim 1, wherein
the first and second capacitor DA converters each further include first and second coupling capacitors,
one end of the first coupling capacitor is connected to one ends of p of the n first up-capacitors and p of the n first down-capacitors corresponding to most significant p bits of the digital code, and the first sampling node,
the other end of the first coupling capacitor is connected to one ends of q of the n first up-capacitors and q of the n first down-capacitors corresponding to least significant q bits excluding the least significant bit of the digital code, where p+q=n,
the one ends of the q first up-capacitors and the q first down-capacitors are connected via the first coupling capacitor to the first sampling node,
one end of the second coupling capacitor is connected to one ends of p of the n second up-capacitors and p of the n second down-capacitors corresponding to the most significant p bits of the digital code, and the second sampling node,
the other end of the second coupling capacitor is connected to the one ends of q of the n second up-capacitors and q of the n second down-capacitors corresponding to the least significant q bits excluding the least significant bit of the digital code, and
the one ends of the q second up-capacitors and the q second down-capacitors are connected via the second coupling capacitor to the second sampling node.

5. The successive approximation AD converter of claim 4, further comprising:
a plurality of first correction capacitors, one ends of the plurality of first correction capacitors being connected to the other end of the first coupling capacitor;
a first capacitor corrector configured to switch connection states between the other ends of the plurality of first correction capacitors and a ground node to which the ground voltage is applied;
a plurality of second correction capacitors, one ends of the plurality of second correction capacitors being connected to the other end of the second coupling capacitor; and
a second capacitor corrector configured to switch connection states between the other ends of the plurality of second correction capacitors and the ground node.

6. The successive approximation AD converter of claim 4, further comprising:
a plurality of first offset adjustment capacitors, one ends of the plurality of first offset adjustment capacitors being connected to the other end of the first coupling capacitor;
a first offset adjuster configured to supply one of the ground voltage and the power supply voltage to the other ends of the plurality of first offset adjustment capacitors;
a plurality of second offset adjustment capacitors, one ends of the plurality of second offset adjustment capacitors being connected to the other end of the second coupling capacitor; and
a second offset adjuster configured to supply one of the ground voltage and the power supply voltage to the other ends of the plurality of second offset adjustment capacitors.

7. The successive approximation AD converter of claim 1, further comprising:
a plurality of first offset adjustment capacitors, one ends of the plurality of first offset adjustment capacitors being connected to the first sampling node;
a first offset adjuster configured to supply one of the ground voltage and the power supply voltage to the other ends of the plurality of first offset adjustment capacitors;
a plurality of second offset adjustment capacitors, one ends of the plurality of second offset adjustment capacitors being connected to the second sampling node; and
a second offset adjuster configured to supply one of the ground voltage and the power supply voltage to the other ends of the plurality of second offset adjustment capacitors.

8. A mobile wireless device comprising:
a receiver configured to receive a wireless signal and output first and second analog signals based on the wireless signal;
the successive approximation AD converter of claim 1 configured to convert the first and second analog signals from the receiver into a digital code; and
a digital signal processor configured to process the digital code obtained by the successive approximation AD converter.

9. A successive approximation AD converter for converting an analog signal into a digital code including (n+1) bit values, where n≧2, comprising:
a capacitor DA converter including n up-capacitors and n down-capacitors each having a binary-weighted capacitance value, one ends of the n up-capacitors and the n down-capacitors being connected to a sampling node, and a supply switch configured to supply one of a ground voltage and a power supply voltage to the other ends of the n up-capacitors and the n down-capacitors;
a sampling switch configured to sample the analog signal for the sampling node during a sampling period;
a comparator configured to compare an analog voltage at the sampling node with a comparative voltage; and
a controller configured to control the supply switch so that, during the sampling period, the ground voltage is supplied to the other ends of the n up-capacitors while the power supply voltage is supplied to the other ends of the n down-capacitors, determine the (n+1) bit values sequentially from a most significant bit value by determining, during each of n bit determination periods corresponding to the n bit values excluding a least significant bit value of the (n+1) bit values and a least significant bit determination period corresponding to the least significant bit value, one corresponding to the bit determination period of the (n+1) bit value based on a result of comparison by the comparator, and control the supply switch based on the result of comparison by the comparator during each of the n bit determination periods so that the analog voltage gradually approaches the comparative voltage.

10. The successive approximation AD converter of claim 9, wherein
during each of the n bit determination periods, if the analog voltage is lower than the comparative voltage, the controller controls the supply switch so that the power supply voltage is supplied to one corresponding to the bit determination period of the n up-capacitors, and if the analog voltage is not lower than the comparative voltage, the controller controls the supply switch so that the ground voltage is supplied to one corresponding to the bit determination period of the n down-capacitors.

11. A mobile wireless device comprising:
a receiver configured to receive a wireless signal and output an analog signal based on the wireless signal;
the successive approximation AD converter of claim 9 configured to convert the analog signal from the receiver into a digital code; and
a digital signal processor configured to process the digital code obtained by the successive approximation AD converter.
